(19) United States
(12) Patent Application Publication
(10) Pub. No.: US 2017/0279024 A1
(43) Pub. Date: Sep. 28, 2017

(54) METHOD OF FORMING A THERMAL BARRIER COATING

(71) Applicants: Patrick E. HOPKINS, Charlottesville, VA (US); Jon F. IHLEFELD, Albuquerque, NM (US); Paul Gilbert CLEM, Albuquerque, NM (US)

(72) Inventors: Patrick E. HOPKINS, Charlottesville, VA (US); Jon F. IHLEFELD, Albuquerque, NM (US); Paul Gilbert CLEM, Albuquerque, NM (US)

(21) Appl. No.: 15/504,255

(22) PCT Filed: Aug. 21, 2015
(86) PCT No.: PCT/US2015/046281

§ 371 Date: Feb. 15, 2017

Related U.S. Application Data
(60) Provisional application No. 62/040,793, filed on Aug. 22, 2014.

(51) Int. Cl. H01L 35/22; F01D 5/28; C01G 33/00; C09D 1/00; C09D 5/00; C23C 18/12; H01L 35/34

(52) U.S. Cl. CPC H01L 35/22; C23C 18/1216; C23C 18/1225; F01D 5/288; H01L 35/34; C09D 1/00; C09D 5/00; C01G 33/006; F05D 2230/90; F05D 2230/41

(57) ABSTRACT

A method of forming a thermal barrier coating is disclosed. The method may include providing a solution containing strontium and niobium and applying the solution to a substrate via a chemical solution deposition process to form a first film layer on the substrate. The method may further include pyrolyzing the first film layer and annealing the first film in an air atmosphere to form a strontium niobate coating.

### CLAIM FOR PRIORITY

This application claims benefit of priority of U.S. Provisional Patent Application No. 62/040,793, filed Aug. 22, 2014, which is incorporated herein by reference.

### TECHNICAL FIELD

The present disclosure is directed to a method of forming coating and, more particularly, to a method of forming a thermal barrier coating.

### BACKGROUND

Thermal barrier coatings (TBC) are materials that are used to protect other materials from potentially damaging effects of exposure to high temperatures. By reducing the effects of prolonged exposure to high temperatures, the coated devices can be used in higher operating temperature applications for longer periods of time. Thermal barrier coatings are commonly applied to components of devices that produce and/or are exposed to high temperatures, such as turbine components (e.g., turbine blades), engine components, exhaust aftertreatment components, etc. In order to effectively protect coated components, thermal barrier coatings generally have good insulating properties and low thermal conductivities (κ).

Some materials used in thermal barrier coatings that also have high electrical conductivity (σ) have been used as thermoelectric (TE) materials in processes for producing electrical power. Thermoelectric materials are materials that generate an electrical voltage when exposed to a temperature gradient. Generally, the efficiency of a thermoelectric material increases as its electrical conductivity σ increases and its thermal conductivity κ decreases. Several known materials have been used in thermoelectric generator systems, such as semiconductors, bismuth telluride, silicides, oxides, and others. Recently, it has been discovered that nano-structured materials can be manufactured to have lower thermal conductivities than previously known materials. As a result, these nano-structured materials have garnered significant interest as both thermoelectric materials and as thermal barrier coatings.

Although nano-structuring has proven to be a somewhat effective way of reducing the thermal conductivity κ of materials, it may not be optimum. For example, known extrinsic mechanisms of nano-structuring, such as superlattices, nano-grains, crystallographic textures, quantum dots, etc., are fabricated using an atomic layer based deposition process that, is costly and may limit the use of such nano-structured materials in commercial applications. Further, known materials may require doping with electrically conductive materials in order to improve their ability to generate thermoelectric power, which can add cost and complexity to coating formation.

The disclosed method addresses one or more of the problems discussed above and/or other problems of the prior art.

### SUMMARY

In one aspect, the present disclosure is directed to a method of forming a thermal barrier coating. The method may include providing a solution containing strontium and niobium and applying the solution to a substrate via a chemical solution deposition process to form a first film layer on the substrate. The method may further include pyrolyzing the first film layer and annealing the first film in an air atmosphere to form a strontium niobate coating.

In another aspect, the present disclosure is directed to a thermal barrier coating deposited on a substrate. The thermal barrier coating may include a strontium niobate coating deposited on the substrate. The strontium niobate coating may be formed by a process that includes providing a coating solution containing strontium and niobium and applying the coating solution to a substrate via a chemical solution deposition process to form a first film on the substrate. The process may further include pyrolyzing the first film layer and annealing the first film in an air atmosphere to form a strontium niobate coating.

In another aspect, the present disclosure is directed to a thermoelectric power generator. The thermoelectric power generator may include a thermoelectric material and a thermal barrier coating deposited on the thermoelectric material. The thermal barrier coating may include a strontium niobate coating. The strontium niobate coating may be formed by a process that includes providing a coating solution containing strontium and niobium and applying the coating solution to the thermoelectric material via a chemical solution deposition process to form a first film on the thermoelectric material. The process may further include pyrolyzing the first film layer and annealing the first film in an air atmosphere to form the strontium niobate coating.

### BRIEF DESCRIPTION OF THE DRAWINGS

FIG. 1 is a cutaway view illustration of an exemplary disclosed turbine, turbine blade, and thermal barrier coating;

FIG. 2 is a pictorial illustration of an exemplary disclosed thermal barrier coating that may be used with the turbine of FIG. 1;

FIG. 3 shows an exemplary disclosed method of forming a thermal barrier coating that may be used to form the thermal barrier coating of FIG. 2;

FIG. 4 shows X-ray diffraction patterns for Sr₂₋ₓLa₂₋ₓNb₂O_{7-δ} films of various thickness that can be produced by the method of FIG. 3;

FIG. 5 shows atomic-resolution HAADF-STEM images of a thermal barrier that can be produced by the method of FIG. 3;

FIG. 6 shows a relationship between film thickness and thermal conductivity;

FIG. 7 shows thermal conductivity versus temperature for two sample layers made by the exemplary disclosed method compared to known materials; and

FIG. 8 shows thermal conductivity versus temperature for two sample layers made by the exemplary disclosed method compared to two models of minimum thermal conductivity.

### DETAILED DESCRIPTION

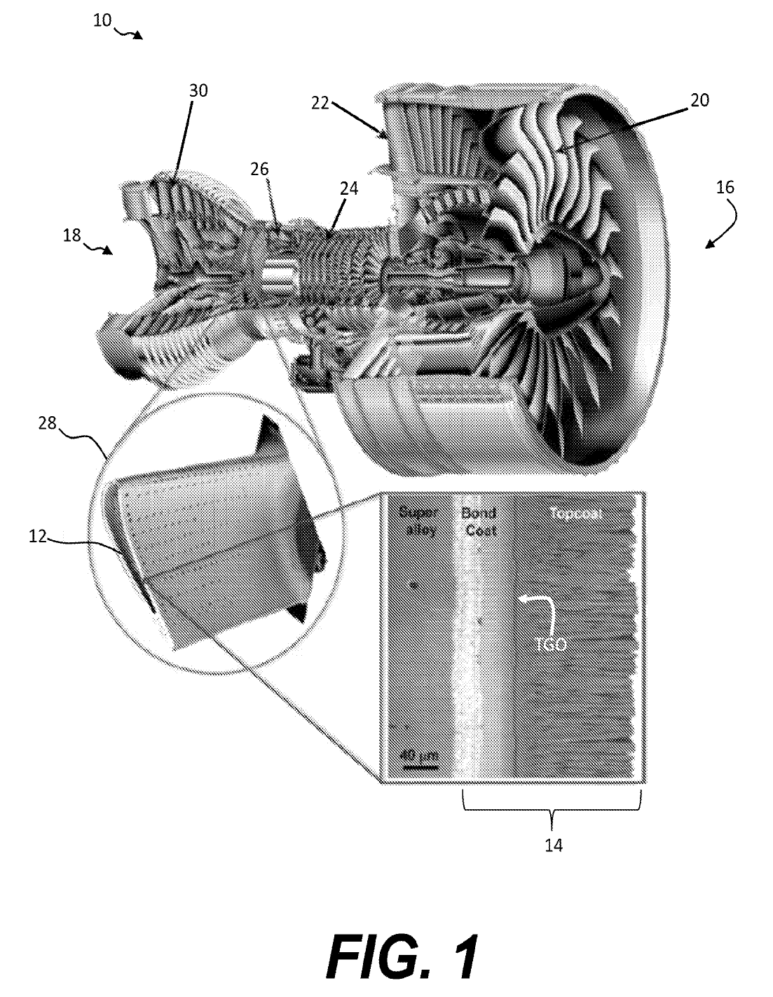

FIG. 1 shows an exemplary turbine system 10 having a turbine blade 12 coated with a protective coating 14, for example, a thermal harrier coating. Although protective coating 14 is shown in FIG. 1 as a coating on turbine blade 12, it is understood that protective coating 14 may be used to coat other types of devices (e.g., engines, furnaces, exhaust aftertreatment devices, etc). Turbine system 10 may include an input end 16 and an output end 18 opposite input end 16. Input end 16 may include a fan 20 operatively coupled to a low-pressure compressor 22 and a high-pressure compressor 24. Fan 20 may draw air into inlet end 16, and compressors 22, 24 may pressurize the air and force the air into a combustor 26. Combustor 26 may be configured to ignite a mixture of air and fuel to generating high-pressure exhaust gases for rotationally driving a high-pressure turbine 28 and a low-pressure turbine 30 at output end 18. Turbines 28, 30 may be operatively coupled to a load (e.g., an electrical generator) via a shall or other means for transmitting rotational energy.

The high pressure exhaust gases generated by combustor 26 may be continually forced through output end 18 of turbine system 10 to rotationally drive high-pressure turbine 28. High-pressure turbine 28 may have a plurality of blades 12 configured to engage the high-pressure exhaust gases and convert thermal energy stored in the high-pressure exhaust gases into rotational energy of high-pressure turbine 28. As the temperature of the high-pressure exhaust gases increases, greater rotational energy may be imparted on high-pressure turbine 28, which may lead to a greater mechanical output of turbine system 10. In some situations, turbine system 10 may be operated to generate high-pressure exhaust gases at relatively high temperatures (e.g., ≧1600° K), which can have deleterious effects on certain materials that may be used to form blades 12 of high-pressure turbine 28.

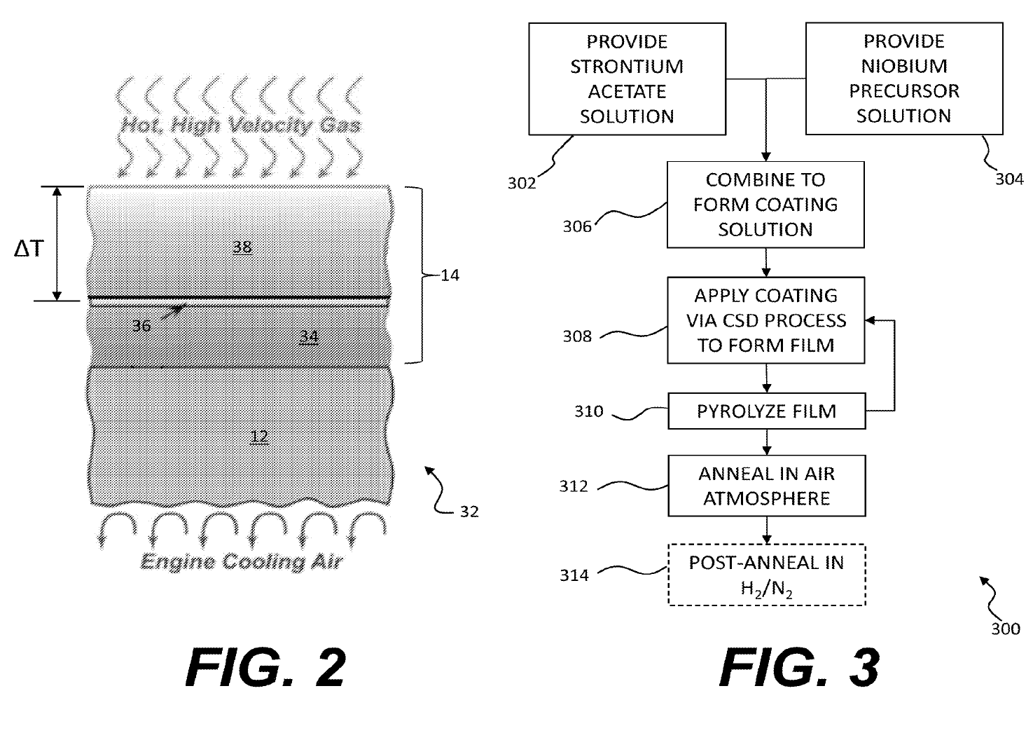

As shown in FIG. 2, blades 12 may have a first side that is primarily exposed to the high-pressure exhaust gases and a second opposite side that is exposed to cooler air (e.g., engine cooling air). To reduce the effects of prolonged exposure to the high-temperature, high-pressure exhaust gases, atmospheric conditions, and other environmental hazards, blades 12 may be coated with protective coating 14. Protective coating 14 may include one or more layers of materials configured to reduce oxidation and heat flow through blades 12, thereby improving the overall lifetime of blades 12. Protective coating 14 may include, for example, an oxidation resistant bond coat 34, a thermally grown oxide (TGO) 36 disposed on oxidant resistant bond coat 34, and a topcoat 38 disposed on thermally grown oxide 36. It is understood that other or fewer materials may be include in protective coating 14.

Topcoat 38 may be a composite layer containing one or more mixtures and/or discrete layers of materials that cooperate to reduce the deleterious effects on blades 12 of prolonged exposure to high temperatures (i.e., topcoat 38 may be a thermal barrier coating) and/or to promote the generation of thermoelectric power. For example, topcoat 38 may include a thermoelectric material that is configured to generate an electrical current when exposed to a temperature gradient. The thermoelectric material of topcoat 38 may be configured to generate an electrical current during operation of turbine system 10 when blades 12 are exposed to the high-temperature exhaust gases on one side and to the cool air on the other (i.e., topcoat 38 may be part of a thermoelectric power generator 32). That is, a temperature difference between the exhaust gases and cool air may create a temperature gradient ΔT across topcoat 38, thereby promoting the generation of thermoelectric power via topcoat 38.

Topcoat 38 may include one or more thermoelectric materials that promote the generation of thermoelectric power by the Seebeck effect. The abilities of such materials to promote the generation of thermoelectric power are sometimes compared according to the Thermoelectric Figure of Merit (ZT). ZT may be defined according to EQ1 below:

$$ZT = \frac{{S}^{2} σ T}{κ} , \qquad EQ 1$$

where S is the Seebeck Coefficient, and T is absolute temperature. As shown in EQ1, ZT, and hence the thermoelectric performance, of thermoelectric materials increases as electrical conductivity σ increases and thermal conductivity κ decreases. Topcoat 38 may include thermoelectric materials such as, for example, semiconductors, oxides, bismuth telluride, silicon-germanium alloys, nanoparticles, and/or superlattices. It is understood that other types of materials may be used.

Topcoat 38 may also include a thermal barrier coating material that is configured to protect blades 12 from the deleterious effects of prolonged exposure to high temperatures while also reducing the thermal conductivity κ of topcoat 38. The thermal barrier coating material may be applied as layers onto topcoat 38, onto thermally grown oxide 36, onto bond coat 34, or onto blades 12. The thermal barrier coating material may, in one example, include one or more layers containing strontium and niobium, such as (0k0)-oriented fiber-textured strontium niobate and/or lanthanum-doped strontium niobate films.

In one embodiment, the layers of a thermal barrier coating may be fabricated by a process that includes, for example, providing a solution containing strontium and niobium, applying the solution to a substrate (i.e., blades 12) via a chemical solution deposition process to form a film on the substrate, and annealing the film in an air atmosphere to form a first strontium niobate coating layer. The process may further include applying the solution to the first strontium niobate coating layer via the chemical solution deposition process to form a subsequent film, and annealing the subsequent film in an air atmosphere to form a subsequent strontium niobate coating layer.

In embodiments where the solution contains lanthanum, the solution may contain, for example, 0-5% lanthanum. Other amounts of lanthanum may be used, if desired. When the solution contains lanthanum, the process of fabricating the layers of the thermal barrier coating material may further include pyrolyzing one or more of the first and subsequent films. The process of applying subsequent layers may be repeated a number of times until a desired density is achieved. After a final layer has been pyrolyzed and annealed, the process of fabricating the thermal barrier coating material may further include post-annealing the thermal barrier coating material. Post-annealing may include annealing in the presence of a forming gas comprising H₂/N₂.

A product of the above described process may include one or more (0k0)-oriented, such as (010)-oriented, layers of Sr₂Nb₂O₂ and/or Sr_{1.9}La_{0.1}Nb₂O_{7-δ}. And as a result of the above described process, these layers may exhibit lower thermal conductivity κ, thereby improving insulating properties and increasing the ZT of topcoat 38. In this way, addition of the thermal barrier coating material to topcoat 38 may improve the performance of topcoat 38 as a thermoelectric material.

It will be apparent to those skilled in the art that various modifications and variations can be made to the disclosed method. Other embodiments will be apparent to those skilled in the art from consideration of the specification and practice of the disclosed method. It is intended that the specification and examples be considered as exemplary only, with a true scope being indicated by the claims included with this specification and their equivalents

### INDUSTRIAL APPLICABILITY

The exemplary disclosed method may be applicable in the formation of thermal barrier coatings to reduce the thermal conductivity κ of the coating and improve its overall ability to protect coated materials from prolonged exposure to high temperatures. The exemplary disclosed method may also be applicable to the formation of thermoelectric materials where it is desirable to supplement materials having high electrical conductivity σ with the addition of materials having lower thermal conductivity κ, thereby increasing the ZT of the thermoelectric material. The exemplary disclosed method may also reduce the cost to produce thermal harrier coatings as well as improved thermoelectric materials by permitting fabrication using chemical solution deposition methods in an air environment. The exemplary disclosed method will now be described with reference to FIG. 3.

The exemplary disclosed method 300 of fabricating a thermal barrier coating may be initiated by providing a strontium acetate solution (Step 302). The method may further include providing a niobium precursor solution (Step 304). The strontium acetate solution and the niobium precursor solution may then be combined to form a coating solution (Step 306). It is noted that Steps 302 and 304 may be performed simultaneously or in the opposite order, if desired. In some embodiments, the coating solution may be doped with lanthanum, such as in the form of lanthanum acetate, before proceeding.

Upon formation of the coating solution, the coating may be applied to a substrate via a chemical solution deposition (CSD) process to form a film layer (Step 308). For example, a spin cast chemical solution deposition process may be used to apply the coating solution. In one example, spin casting may be performed at 3000 RPM for about 30 seconds. Other rotational speeds and time periods may be used, if desired.

The film layer may then be pyrolyzed at about 300° C. for about 5 minutes (Step 310). Pyrolysis may, for example, be performed on a hot plate under an air atmosphere. After pyrolysis, the coating solution may be re-applied using by the chemical solution deposition process of Step 308 to apply a subsequent film and increase the density of strontium and niobium on the substrate. Steps 308 and 310 may be repeated a number of times, if desired, until a number of subsequent films have been applied and a desired density of material has been deposited on the substrate.

The deposited as-pyrolyzed films may then be annealed at about 1000° C. for about 5 minutes in an air atmosphere to crystalize the as-pyrolyzed films (Step 312). When only a first film layer is deposited, the first film may be annealed to form a strontium niobate coating. When multiple film layers are deposited, the first and subsequent film layers may be annealed to form the strontium niobate coating. In one embodiment, annealing may be performed by placing the products of pyrolysis into an oven in an air atmosphere. The results of annealing may include one or more (0k0)-oriented, such as (010)-oriented, layers of Sr₂Nb₂O₇ and/or Sr_{1.9}La_{0.1}Nb₂O_{7-δ}. And as a result of the above described process, these layers may exhibit lower thermal conductivity κ, thereby improving its insulating properties and increasing the ZT of topcoat 38. In this way, addition of the thermal barrier coating material to topcoat 38 may improve its performance as a thermoelectric material.

When the coating solution contains lanthanum, the method may further include post-annealing the strontium niobate coating (Step 314). Post-annealing the strontium niobate coating when the coating solution contains lanthanum may promote solubility of the lanthanum and activate electronic carriers for thermoelectric applications.

### Experiment

### Procedure

In an exemplary experiment, (0k0)-oriented fiber-textured strontium niobate and lanthanum-doped strontium niobate films were prepared on SrTi0₃ substrates. A chelate-based chemical solution deposition approach was used where strontium or strontium and lanthanum acetates were dissolved in propionic acid and niobium butoxide was chelated with six molar equivalents of acetic acid. An appropriate amount of the dissolved acetates was added to the niobium precursor, as measured by constituent masses, and the solutions were diluted to 0.15M with anhydrous ethanol. Solutions were spin cast onto (001)-oriented SrTiO₃ single crystalline substrates at 3000 RPM for about 30 seconds and pyrolyzed on a hot plate in air at about 300° C. for five minutes. Sr₂Nb₂O₇ and Sr_{1.9}La_{0.1}Nb₂O_{7-δ} films were formed by annealing the as-pyrolyzed films to about 1000° C. in an air atmosphere for about 5 minutes by directly inserting the samples into a preheated furnace. After the final deposition and crystallization anneal, the La-containing films were post-annealed in a dry 3% H₂/N₂ atmosphere to promote solubility of the lanthanum and to activate electronic carriers for thermoelectric applications. The coating/pyrolysis/crystallization process was repeated to increase film thickness to an as-crystallized individual layer thickness of 27 nm.

The phase-assemblage and orientation of the films were confirmed via X-ray diffraction (XRD) using a Philips MPD materials diffractometer equipped with monochromators for Cu-Kα radiation. Scanning transmission electron microscopy (STEM) images were generated using an FEI-Titan G2 instrument, operated at 200 keV and equipped with a high angle annular dark field (HAADF) detector. The thermal conductivities of the samples were determined using time-domain thermoreflectance (TDTR) where the experimental data was fit to a multi-layer thermal model. To provide the transducer for the optical measurements, an aluminum film was deposited on the samples by electron beam evaporation. The film was approximately 90 nm thick, as confirmed by picosecond ultrasonics. For this experiment, the pump-beam was modulated using a linearly amplified 11.39 MHz sinusoid and the ratio of the in-phase to out-of-phase signals from the probe beam was monitored using a lock-in amplifier (SRS 844). Additionally, literature values were assumed for the heat capacities of Al and Sr₂Nb₂O₇, as well as the bulk thermal properties of SrTiO₃.

### Results and Discussion

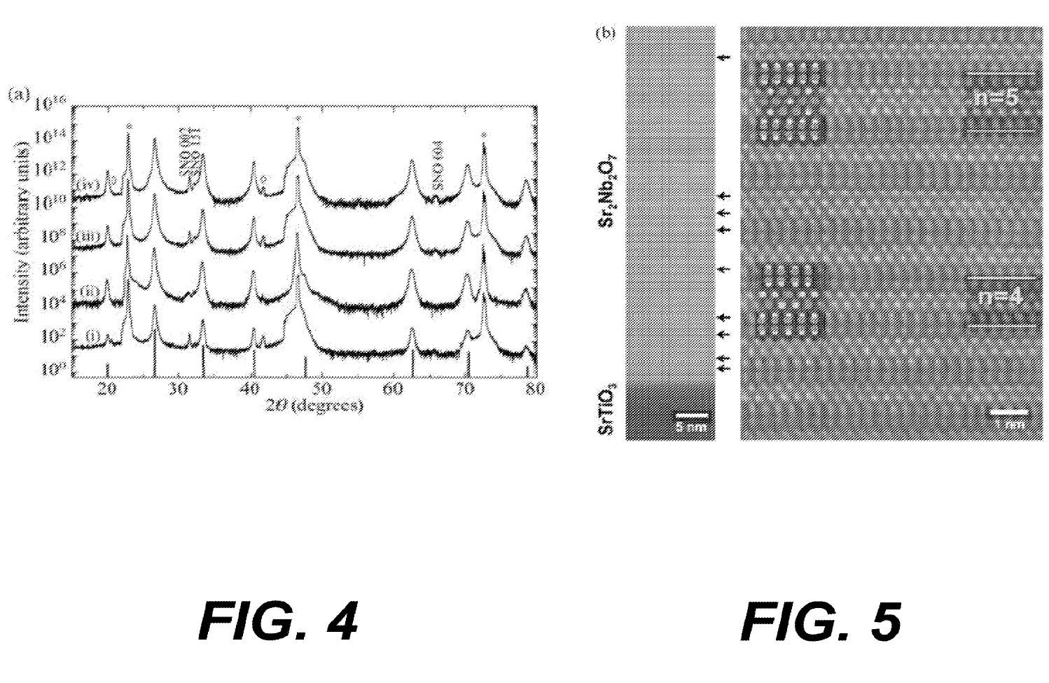

FIG. 4 shows a representative group of X-ray diffraction patterns for Sr₂₋ₓLaₓNb₂O_{7-δ} films of various thicknesses doped with 5% lanthanum (x=0.1). X-ray diffraction reveals highly (0k0)-oriented films for each thickness. Minority peaks associated with the (002) and (151) reflections were also observed, but constituted less than 3% of the diffracting volume based upon comparison of measured intensities and those expected from a random powder pattern. These films were previously known to possess a random in-plane orientation and therefore are fibertextured. Also, while single crystalline substrates were utilized in this study, (010)-fiber texture was identified on non-lattice-matched and polycrystalline substrates, demonstrating a preferred (010) out-of-plane orientation regardless of substrate, which makes this technique/materials system uniquely manufacturable for thermal applications.

FIG. 5 shows atomic-resolution HAADF-STEM images illustrating the layered crystal structure of strontium niobate. The left image depicts the interface between the thin film and SrTiO₃ substrate, confirming that the layers are well aligned with the substrate. The right image in FIG. 5 shows details of an individual Sr₂Nb₂O₇ grain that was tilted, in the microscope, to a (101)-type orientation, allowing the layered structure to be imaged directly. These observations identify the presence of defects in the layering sequence. In the ideal Sr₂Nb₂O₇ crystal structure, the NbO₆-octahedra are arranged in slabs that are 4-octahedra wide along the b-axis. However, more generally within the SrₙNbₙO₃ₙ₊₂ homologous series (for which Sr₂Nb₂O₇ corresponds to n=4), slab widths of both 4 and 5 NbO₆-octahedra have been observed; for instance, the Sr₅Nb₅O₁₇ structure (the n=5 member of the homologous series) consists entirely of slabs that are 5 octahedra-wide. Examples of individual n=4 and n=5 slabs are indicated on FIG. 5 with the superimposed Sr and Nb atom positions from (101) projections of Sr₂Nb₂O₇ and Sr₅Nb₅O₁₇. The arrows on FIG. 5 indicate the distribution of n=5 slabs across one grain. At this defect density (9 slabs of the n=5 phase versus 34 slabs of n=4 present within the left image), it was calculated that there is a small amount of oxygen reduction by δ=0.05 in the Sr₂₋ₓLaₓNb₂O_{7-δ} samples. To confirm the results were not sensitive to this low level of reduction, an additional sample (x=0.1, approximately 220 nm thick) was prepared through chemical solution deposition, but done so in oxidizing atmospheres to discourage the formation of the n=5 slabs.

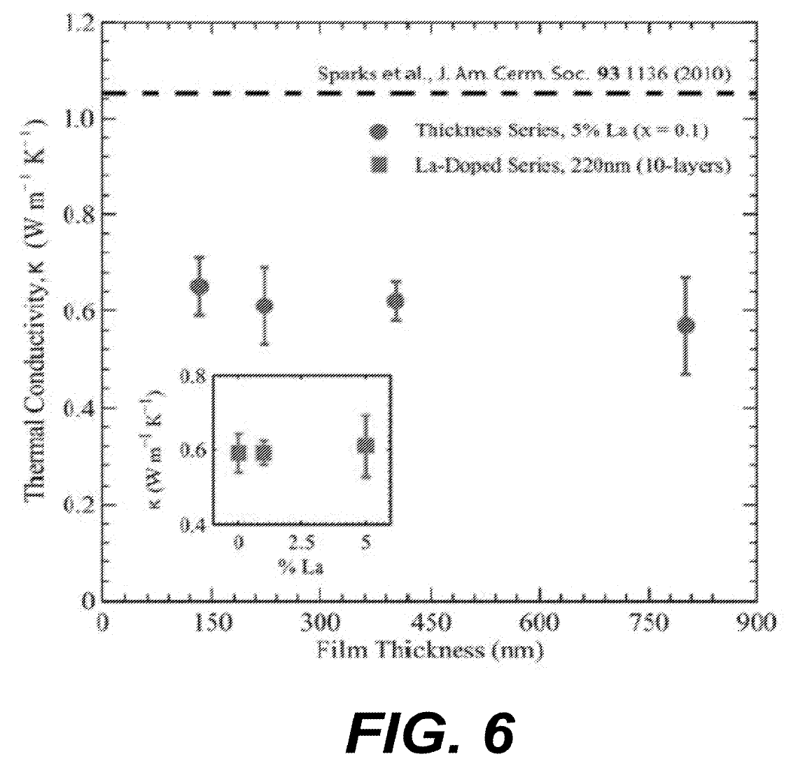

FIG. 6 shows the measured thermal conductivities of exemplary Sr₂₋ₓLaₓNb₂O_{7-δ} thin films as a function of both film thickness (x=0.1) and doping with lanthanum (constant film thickness) at room temperature. The error bars encompass the uncertainty in the thickness of the 90 nm aluminum film deposited on the samples to serve as a transducer for the optical measurement, as well as the standard deviation about the mean for the three measurements made on each sample. Measurement of the single sample prepared in oxidizing atmospheres yielded a thermal conductivity of 0.60 W m⁻¹ K⁻¹ (±0.03 W m⁻¹ K⁻¹). This value is of the same magnitude as the samples in both the thickness and doping series, thereby confirming that (a) the presence of minority fractions of the Sr₅Nb₅O₁₇ phase has minimal effect on the cross-planer thermal conductivity κ, and (b) that the electrical contribution to κ as a result of La-doping coupled with different annealing conditions is dwarfed by the phonon contribution.

Additionally, FIG. 6 shows the thermal conductivity along the b-axis of textured, hot-forged ceramic Sr₂₋ₓLaₓNb₂O_{7-δ} samples (x=0.01). A 40-45% reduction in the thermal conductivity κ of the thin films was observed versus bulk samples measured via thermal flash. This reduction is not believed to be caused by film boundary scattering, since κ is independent of film thickness, as shown in FIG. 6. If boundary scattering were playing a role in the observed reduction, one would expect κ to increase with increasing film thickness, asymptotically approaching the previously mentioned bulk value. Similarly, no variation in κ is seen due to different dopant-concentrations of lanthanum, revealing that neither impurity nor film boundary scattering are dominant phonon scattering mechanisms in these samples. Alternatively, phonons are more readily scattered at the weakly-bonded interfaces between alternating layers of the Sr₂Nb₂O₇ parent structure.

The difference in thermal conductivity along the b-axis of the exemplary disclosed films compared with the previously mentioned hot-forged ceramics likely stems from the degree of texture present in the different sample sets. These exemplary films have significantly fewer non-0k0 peaks present in the X-ray diffraction pattern, and the intensities of non-(0k0) peaks relative to 0k0 peaks are lower than those previously reported. Given the high degree of crystallographic anisotropy present, the lower thermal conductivity κ values observed stem from a higher degree of texture owing to sampling a high concentration of 0k0-oriented material.

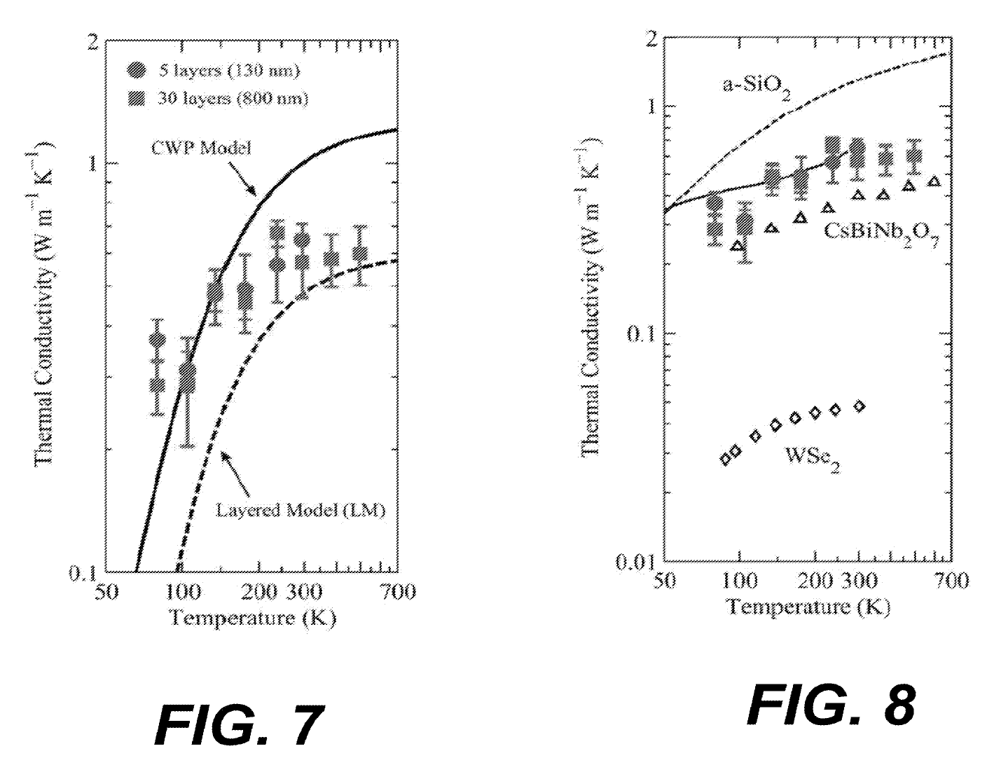

The thermal conductivity of two La-doped samples (x=0.1) with different film thicknesses (130 nm and 800 nm, respectively) were measured as a function of temperature from 80-500K. FIG. 7 is a plot of these data along with previous measurements of several materials, including those with weakly-bonded, naturally-layered structures as well as amorphous SiO₂ (a-SiO₂). Like the other layered-structures shown in FIG. 7, the thermal conductivities κ of both Sr_{1.9}La_{0.1}Nb₂O_{7-δ} films are less than a-SiO₂ across the temperature range, demonstrating the strong role that phonon scattering at weakly bonded layers can have on the thermal conductivity κ of crystalline materials. Additionally, the data show good agreement with values for bulk single-crystalline Sr₅Nb₅O₁₇ samples (exclusively composed of n=5 material in the SrₙNbₙO₃ₙ₊₂ homologous series) measured via a thermocouple-based, steady state technique. Lastly, the thermal conductivity of Sr_{1.9}La_{0.1}Nb₂O_{7-δ} is larger than that of other known layered material systems, including CsBiNb₂O₇ and WSe₂. This is consistent with the fact that the cross-plane (b-axis) longitudinal speed of sound (v_{L}) in Sr₂Nb₂O₇ is 5192 m/s, which is larger than the similarly-directed sound velocities of the aforementioned known materials (v_{L} equal to 3350 m/s and 1650 m/s, respectively). The differences in the cross-plane sound velocities of these materials can be attributed to the strength of the bonding between the layers; the bonds between WSe₂ layers being the weakest while those between “perovskite-slabs” in Sr_{1.9}La_{0.1}Nb₂O_{7-δ} being the strongest. The weaker bonds lead to stronger phonon scattering at the layer interfaces, leading to lower thermal conductivities κ.

To investigate the nature of thermal transport in the exemplary Sr_{1.9}La_{0.1}Nb₂O_{7-δ} layered structures, the minimum limit model for thermal conductivity κ was used. Assuming an isotropic Debye solid, the expression for the minimum phonon thermal conductivity is shown in EQ2 below:

$$\frac{{ℏ}^{2}}{6 {π}^{2} {k}_{B} {T}^{2}} {\sum }_{j} {\int }_{0}^{{ω}_{c} \cdot j} {τ}_{m i n , j} \frac{{ω}^{4}}{{v}_{j}} \frac{exp [ \frac{ℏ ω}{{k}_{B} T} ]}{{( exp [ \frac{ℏ ω}{{k}_{B} T} ] - 1 )}^{2}} d ω , \qquad EQ 2$$

where the summation is over the three acoustic phonon modes (one longitudinal, two transverse) and j denotes the particular mode, h is the reduced Planck's constant, ω is the phonon angular frequency, ω_{cj} is the cutoff frequency, T is the temperature, vⱼ is the phonon group velocity and τₘᵢₙⱼ is the minimum scattering time. To evaluate EQ2 for the exemplary material system, v_{L}=5192 m/s was used to calculate v_{T}=v_{L}\sqrt{(c₅₅/c₂₂)} using known literature values for the elastic constants of Sr₂Nb₂O₇. Additionally, n=72.993 nm⁻³ was used for the atomic density of Sr₂Nb₂O₇ in calculating the cutoff frequencies (ω_{cj}=vⱼ(6π²n)^{1/3}).

FIG. 8 shows disclosed La-doped films of different thicknesses along with two versions of the model described by EQ2. The solid line is the Cahill-Watson-Pohl (CWP) model, and the dashed line is a modified version of the CWP referred to as the layered model (LM). Layered model calculations include the effects of scattering between weakly bonded layers. The data lie below the expected minimum thermal conductivity κ predicted by the CWP model. The difference between the two models lies in the definition of τₘᵢₙ; the CWP model defines the minimum scattering time to be one-half the period of oscillation between adjacent atoms in a given material, τ_{minj,CWP}=π/ω. The layered model incorporates an additional term via Matthiessen's rule that accounts for scattering at the interface between two different layers. The minimum scattering time thus takes the form shown in EQ3 below:

$${τ}_{m i n , j , LM} = {( \frac{ω}{π} + {v}_{j} \frac{{π}^{s} n}{{ω}^{2}} {( {v}_{j} - \frac{ω d}{π} )}^{2} )}^{- 1} , \qquad EQ 3$$

where the first term is the scattering within the layers and the second is the scattering between layers, which is dependent on the separation distance, d. In the case of small d and weak bonding between layers (resulting in lower Debye cutoff frequencies), the difference between the modal sound speed and inter-layer velocities is maximized, resulting in scattering times that approach the inter-atomic scattering times obtained using the CWP model. The result is a reduction in the predicted minimum thermal conductivity κ due to the combined contributions of these separate scattering mechanisms. As we can see in FIG. 8, the layered model lies below the exemplary measured data suggesting that the incorporation of inter-layer scattering successfully establishes a new theoretical minimum thermal conductivity κ that is applicable to similarly layered structures.

This work highlights several important features of the naturally-layered Sr₂₋ₓLaₓNb₂O_{7-δ} material system that are relevant to a variety of application areas. First, it has been shown that both the film thickness and lanthanum doping have little to no effect on the cross-plane (b-axis) thermal conductivity of the exemplary samples, indicating that the electrical and thermal properties of these films can be tuned independently over the doping range discussed herein. This conclusion is particularly significant in the scope of using strontium niobate as a high-temperature thermoelectric material. Second, the scalable-nature of the fabrication process used to synthesize these exemplary thin films and the exceptional degree of crystallinity and crystallographic texture confirmed via X-ray diffraction and STEM is significant. It has been shown that the thermal conductivities of the disclosed chemical solution deposition-fabricated thin films (0.6 W m⁻¹ K⁻¹) are comparable to that of similarly layered film structures created via epitaxial growth processes. The ability to fabricate these highly insulative films through such a simple process both quickly and inexpensively on a broad variety of substrates without requiring lattice-matching epitaxy not only reinforces their potential as a commercial thermoelectric, but also as a next-generation thermal barrier coating to protect critical components in high-temperature operating environments.

What is claimed is:

1. A method of forming a thermal barrier coating, the method comprising:
providing a coating solution containing strontium and niobium;
applying the coating solution to a substrate via a chemical solution deposition process to form a first film layer on the substrate;
pyrolyzing the first film layer; and
annealing the first film layer in an air atmosphere to form a strontium niobate coating.

2. The method of claim 1, further including:
re-applying the coating solution via the chemical solution deposition process to form a subsequent film layer;
pyrolyzing the subsequent film layer; and
annealing the first and subsequent film layers in an air atmosphere to form the strontium niobate coating layer.

3. The method of claim 2, wherein the strontium niobate coating includes one or more (0k0)-oriented films.

4. The method of claim 3, wherein the strontium niobate coating includes one or more (010)-oriented films.

5. The method of claim 3, wherein the solution contains lanthanum.

6. The method of claim 5, wherein the solution contains 0-5% lanthanum.

7. The method of claim 6, wherein the strontium niobate coating comprises one or more of Sr₂Nb₂O₇ and Sr_{1.9}La_{0.1}Nb₂O_{7-δ}.

8. The method of claim 7, further including post-annealing the strontium niobate coating in the presence of a forming gas comprising H₂/N₂.

9. A thermal barrier coating deposited on a substrate, the thermal barrier coating comprising:
a strontium niobate coating layer deposited on the substrate wherein the strontium niobate coating is formed by a process comprising:
providing a coating solution containing strontium and niobium;
applying the coating solution to a substrate via a chemical solution deposition process to form a first film layer on the substrate;
pyrolyzing the first film layer; and
annealing the first film layer in an air atmosphere to form the strontium niobate coating.

10. The thermal barrier coating of claim 9, wherein the process further includes:
re-applying the coating solution via the chemical solution deposition process to form a subsequent film layer;
pyrolyzing the subsequent film layer; and
annealing the first and subsequent film layers in an air atmosphere to form the strontium niobate coating.

11. The thermal barrier coating of claim 10, wherein the solution contains lanthanum.

12. The thermal barrier coating of claim 11, wherein the solution contains 0-5% lanthanum.

13. The thermal barrier coating of claim 11, wherein:
the strontium niobate coating includes one or more (0k0)-oriented films; and
the strontium niobate coating comprises one or more of Sr₂Nb₂O₇ and Sr_{1.9}La_{0.1}Nb₂O_{7-δ}.

14. The thermal barrier coating of claim 13, wherein the strontium niobate coating includes one or more (010)-oriented films.

15. The thermal barrier coating of claim 13, wherein the process further includes post-annealing the strontium niobate coating in the presence of a forming gas comprising H₂/N₂.

16. A thermoelectric power generator, comprising:
a thermoelectric material; and
a thermal barrier coating deposited on the thermoelectric material, wherein the thermal barrier coating comprises a strontium niobate coating, the strontium niobate coating being formed by a process comprising:
providing a coating solution containing strontium and niobium;
applying the coating solution to the thermoelectric material via a chemical solution deposition process to form a first film layer on the thermoelectric material;
pyrolyzing the first film layer; and
annealing the first film layer in an air atmosphere to form the strontium niobate coating.

17. The thermoelectric power generator of claim 16, wherein the process further comprises:
re-applying the coating solution via the chemical solution deposition process to form a subsequent film layer;
pyrolyzing the subsequent film layer; and
annealing the first and subsequent film layers in an air atmosphere to form the strontium niobate coating.

18. The thermoelectric device of claim 17, wherein:
the strontium niobate coating includes one or more (0k0)-oriented films; and
the strontium niobate coating comprises one or more of Sr₂Nb₂O₇ and Sr_{1.9}La_{0.1}Nb₂O_{7-δ}.

19. The thermoelectric device of claim 18, wherein the process further includes post-annealing the strontium niobate coating in the presence of a forming gas comprising H₂/N₂.

20. The thermoelectric device of claim 19, wherein the thermoelectric device is disposed on a blade of a turbine system.
